(19) United States
(12) Patent Application Publication
(10) Pub. No.: US 2004/0218350 A1
(43) Pub. Date: Nov. 4, 2004

(54) Containment system for computer equipment

(76) Inventor: Michael John Sargeant, Wokingham (GB)

Correspondence Address: BARNES & THORNBURG, P.O. BOX 2786, CHICAGO, IL, 60690-2786, US

(21) Appl. No.: 10/814,898

(22) Filed: Mar. 31, 2004

(30) Foreign Application Priority Data
Apr. 29, 2003 (GB) GB 0309706.0

(51) Int. Cl. H05K 5/00

(52) U.S. Cl. 361/679

(57) ABSTRACT

A containment system comprises first and second containment units. The first containment unit comprises a plurality of sections removably fastened together to form a first enclosure for a computer module, with a plurality of fastening holes for allowing the first containment unit to be fastened to a fixed object, and with a pair of strengthening flanges extending parallel to each other in an outward direction. The second containment unit comprises a plurality of sections removably fastened together to form a second enclosure for a display screen, the second enclosure being tiltably mounted on a base to allow the position of the display screen to be adjusted, and the base having a plurality of fastening holes for allowing it to be fastened to a fixed object. The second containment unit is dimensioned to be nestable between the strengthening flanges of the first containment unit.

### BACKGROUND OF THE INVENTION

This invention relates to a containment system for computer equipment.

In certain applications, such as on sea vessels, there is a requirement for computer equipment to be mounted securely, so as to retain it in the event of shock or vibration. The object of the present invention is to provide a novel containment system for this purpose.

### SUMMARY OF THE INVENTION

According to the invention, there is provided a containment system for equipment comprising at least a computer module and a display screen, the system comprising:

a) a first containment unit, comprising a plurality of sections removably fastened together to form a first enclosure for containing the computer module, with a plurality of fastening holes for allowing the first containment unit to be fastened to a fixed object, and with a pair of strengthening flanges extending parallel to each other in an outward direction; and

b) a second containment unit comprising a plurality of sections removably fastened together to form a base and a second enclosure for containing the display screen, the second enclosure being tiltably mounted on the base to allow the position of the display screen to be adjusted, and the base having a plurality of fastening holes for allowing it to be fastened to a fixed object;

c) wherein the second containment unit is dimensioned to be nestable between the strengthening flanges of the first containment unit.

### BRIEF DESCRIPTION OF THE DRAWINGS

One containment system in accordance with the invention will now be described by way of example with reference to the accompanying drawings.

FIGS. 1a to 1c are plan, front and side views of a first part of a first containment unit.

FIGS. 2a to 2c are plan, front and side views of a second part of the first containment unit.

FIGS. 3a to 3c are plan, front and side views of a first part of a second containment unit.

FIGS. 4a to 4c are plan, front and side views of a second part of the second containment unit.

FIG. 5 shows how the first and second parts of the first containment unit fit together.

FIG. 6 shows how the first and second parts of the second containment unit fit together.

FIG. 7 shows how the second containment unit nests with the first containment unit.

FIG. 8 shows a possible modification of the first containment unit.

### DESCRIPTION OF AN EMBODIMENT OF THE INVENTION

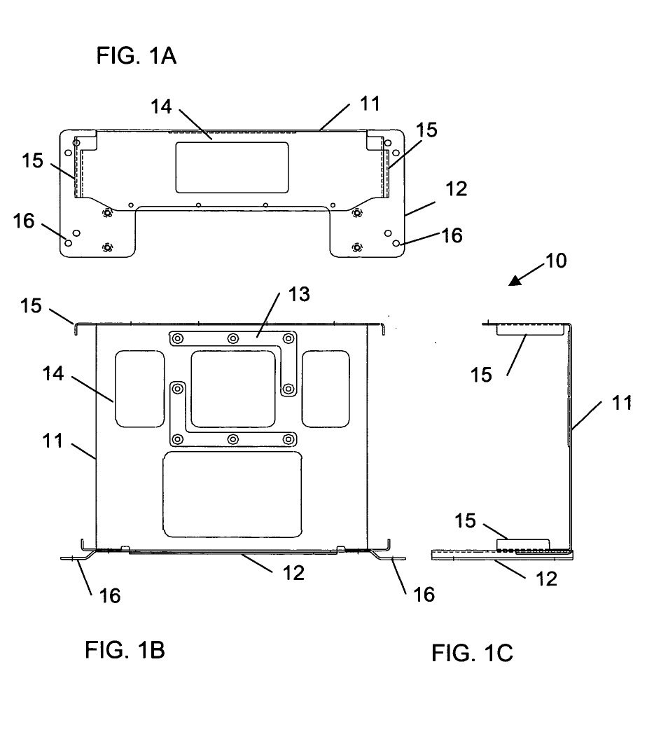

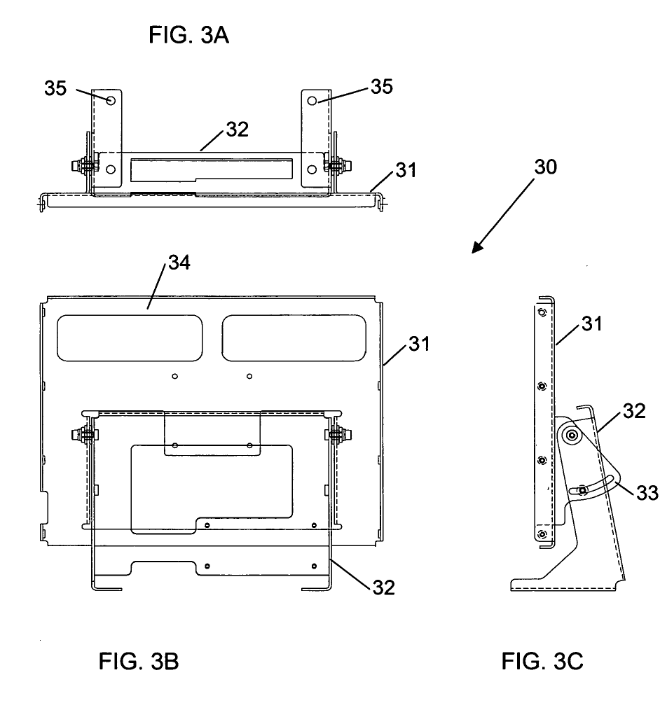

The containment system comprises a computer module containment unit (FIGS. 1, 2 and 5), and display containment unit (FIGS. 3, 4 and 6). The system preferably also includes further containment units (not shown) for holding a keyboard and mouse.

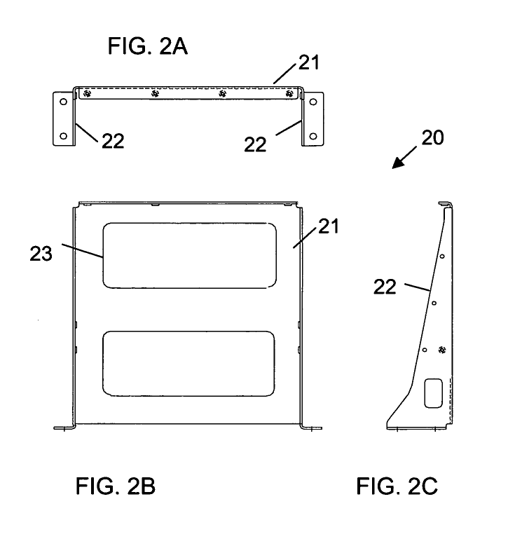

The computer module containment unit consists of a housing 10 (FIG. 1) and a closure member 20 (FIG. 2).

The housing 10 is formed from two sheet metal components 11 and 12, spot-welded together to form three sides of a generally rectangular box structure. In this example the box is dimensioned to receive a computer module (not shown) approximately 400×300×100 mm in size. L-shaped plates 13 are spot-welded to the component 11 to increase its rigidity. Cut-outs 14 give access to the computer module, and also to reduce the weight of the unit. Integral lugs 15 at the top and bottom of the box prevent longitudinal movement of the computer module. Rubber pads (not shown), glued to the lugs and elsewhere, hold the computer module securely.

The closure member 20 is a single sheet metal component, consisting of a rectangular panel 21 with two triangular flanges 22 extending parallel to each other at right angles to the rectangular panel. These strengthen and provide rigidity for the containment unit. Cut-outs 23 provide access and to reduce weight.

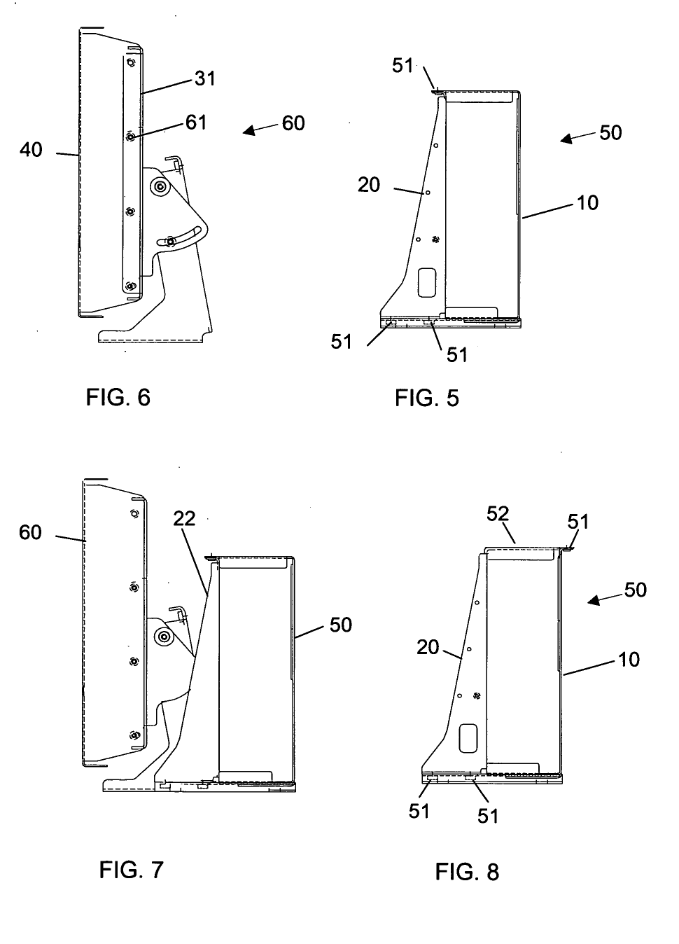

As shown in FIG. 5, the computer module containment unit 50 is assembled by locating the computer module (not shown) in the housing 10 and then removably fastening the closure member 20 to the housing 10 by bolts 51 at top and bottom, to provide the fourth side of the box. The whole unit can be secured to a fixed surface (e.g. a desk), by means of screws through mounting holes 16.

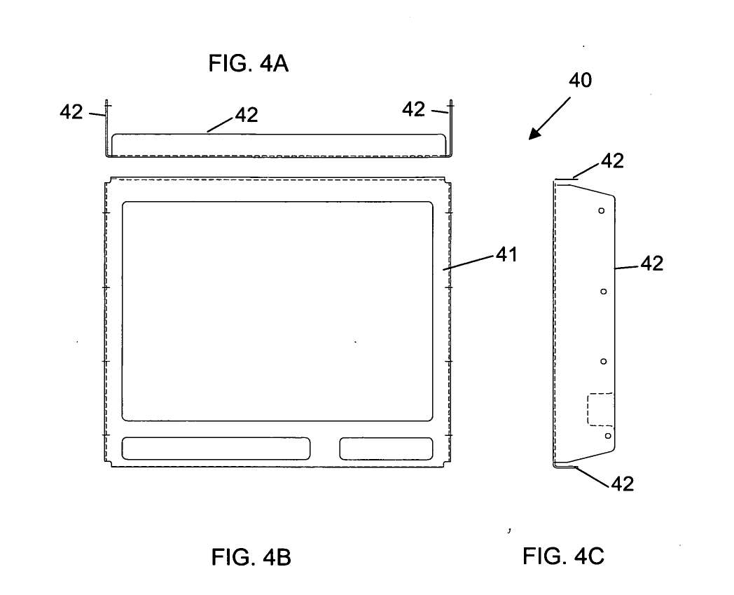

The display containment unit consists of an adjustable stand 30 (FIG. 3) and a bezel 40 (FIG. 4).

The adjustable stand 30 comprises a sheet metal back plate 31, mounted on a base 32 by a lockable tilt mechanism 33. In this example, the back plate is dimensioned to receive an LCD display unit (not shown), approximately 400×300×50 mm in size. Cut-outs 34 are provided for access to the back of the display unit and to reduce weight. The unit can be screwed down to a fixed surface (e.g. a desk), by means of mounting holes 35 in the base.

The bezel 40 is formed from sheet metal, and comprises a rectangular frame-shaped portion 41 with four integral lugs 42.

Referring to FIG. 6, the display containment unit 60 is assembled by locating the display unit (not shown) on the back plate 31, and then removably fastening the bezel 40 to the back plate 31, by screws 61, so as to hold the display unit firmly in place.

Referring to FIG. 7, the display containment unit 60 is designed to be nestable between the triangular flanges 22 of the computer module containment unit 50. This reduces the overall envelope of the assembly, ensuring that it fits into a compact cube.

Some Possible Modifications

It will be appreciated that many modifications may be made to the system described above without departing from the scope of the present invention. For example, the system may be adapted to hold different shapes and sizes of computer module and display unit.

Referring to FIG. 8, in one particular modification the top horizontal section 52 of the computer module containment unit 50 is formed integrally with the part 20, rather than with part 10. In other words, in this version the computer module containment unit 50 is formed from two generally L-shaped parts, each of which provides two sides of the rectangular box structure. As before, the parts 10, 20 are removably fastened together by bolts 51.

What is claimed is:

1. A containment system for equipment comprising at least a computer module and a display screen, the system comprising:
a) a first containment unit, comprising a plurality of sections removably fastened together to form a first enclosure for containing the computer module, with a plurality of fastening holes for allowing the first containment unit to be fastened to a fixed object, and with a pair of strengthening flanges extending parallel to each other in an outward direction; and
b) a second containment unit comprising a plurality of sections removably fastened together to form a base and a second enclosure for containing the display screen, the second enclosure being tiltably mounted on the base to allow the position of the display screen to be adjusted, and the base having a plurality of fastening holes for allowing it to be fastened to a fixed object;
c) wherein the second containment unit is dimensioned to be nestable between the strengthening flanges of the first containment unit.

2. A containment system according to claim 1 wherein said strengthening flanges are formed integrally with one of said plurality of sections of the first containment unit.

3. A containment system according to claim 1 wherein said first containment unit comprises a first section, forming three sides of a generally rectangular box structure, and a second section, forming a fourth side of said generally rectangular box structure.

4. A containment system according to claim 3 wherein said strengthening flanges are formed integrally with said second section.

5. A containment system according to claim 1 wherein said first containment unit comprises a first section, forming two sides of a generally rectangular box structure, and a second section, forming third and fourth sides of said generally rectangular box structure.

6. A containment system according to claim 1, wherein the first and second containment units are formed from a plurality of sheet-metal components.

7. A containment system according to claim 6 further including a plurality of plates, spot-welded to at least one of said sheet-metal components, to increase the rigidity thereof.

8. A containment system according to claim 6, wherein at least one of said sheet-metal components has at least one cut-out to provide access and to reduce weight.

9. A containment system according to claim 1 further including a plurality of resilient pads attached to said first containment unit for holding said computer module securely within said first containment unit.

10. A containment system according to claim 1 wherein said display screen comprises a liquid crystal display (LCD).
